(19) United States
(12) Patent Application Publication
(10) Pub. No.: US 2009/0014852 A1
(43) Pub. Date: Jan. 15, 2009

(54) Flip-Chip Packaging with Stud Bumps

(76) Inventor: Hsin-Hui Lee, Kaohsiung (TW)

Correspondence Address: SLATER & MATSIL, L.L.P., 17950 PRESTON ROAD, SUITE 1000, DALLAS, TX, 75252, US

(21) Appl. No.: 11/776,387

(22) Filed: Jul. 11, 2007

(51) Int. Cl. H01L 23/495; H01L 21/00; H01L 23/48

(52) U.S. Cl. 257/676; 257/737; 438/123; 257/E23.031; 257/E23.01

(57) ABSTRACT

A method for forming a package structure is provided. The method includes providing a semiconductor die; providing a package substrate; forming stud bumps on the package substrate; and bonding the semiconductor die to the package substrate, wherein the stud bumps electrically connect the semiconductor die and the package substrate.

### TECHNICAL FIELD

This invention relates generally to packaging processes for integrated circuits, and more particularly to flip-chip packaging of semiconductor dies using stud bumps.

### BACKGROUND

Modern integrated circuits are made up of literally millions of active devices such as transistors and capacitors. These devices may be initially isolated from each other, but are later interconnected together to form functional circuits. Typical interconnection structures include lateral interconnections, such as metal lines (wirings), and vertical interconnections, such as vias and contacts. Interconnections are increasingly determining the limits of performance and the density of modern integrated circuits.

On top of the interconnection structures, bond pads are formed and exposed on the surface of the respective chip. Electrical connections are made through bond pads to connect the chip to a package substrate. Bond pads can be used for wire bonding or flip-chip bonding.

FIGS. 1 through 2B illustrate conventional flip-chip packaging methods. Referring to FIG. 1, die 10 includes bond pads 12 on its top surface, wherein bond pads 12 are connected to the integrated circuits in die 10. Stud bumps 14 are formed on bond pads 12 by bond head 16 of a wire-bonding tool (not shown). After making each of the bonds on die 10, the wire-bonding tool applies a force to cut the respective bond wire, leaving stud bumps 14 attached to bond pads 12.

In FIG. 2A, die 10 is flip-bonded onto package substrate 16. Typically, the bonding process involves placing stud bumps 14 against bond pads 18 on package substrate 16, with solder balls 20 between stud bumps 14 and the respective bond pads 18. A reflow is then performed to melt solder balls 20, so that stud bumps 14 are electrically connected to bond pads 18.

FIG. 2B illustrates another flip-chip bonding scheme, wherein die 10 is flip-bonded onto package substrate 16 through anisotropic conducting film (ACF) 22. ACF 22 has the ability to electrically connect stud bumps 14 to the corresponding underlying bond pads 18, without providing lateral electrical paths for shorting neighboring stud bumps 14 and bond pads 18.

Using stud bumps to packaging semiconductor dies has the advantageous feature of lowering the packaging cost. However, the conventional method of forming stud bumps suffers drawbacks. Referring back to FIG. 1, when a bond wire is disconnected from the respective stud bumps 14, a force has to be applied. As a result, bond pads 12 may be delaminated from die 10. Since die 10 typically includes low-k dielectric materials for forming interconnect structures, it is highly likely that the delamination occurs at the low-k dielectric materials. With the advancement of integrated circuit formation technology, dielectric materials with increasingly lower k values are used, and hence further increasing the possibility of delamination. Solutions are thus needed.

### SUMMARY OF THE INVENTION

In accordance with one aspect of the present invention, a method for forming a package structure includes providing a semiconductor die; providing a package substrate; and forming stud bumps between, and electrically connecting, the semiconductor die and the package substrate. The stud bumps each has a first portion closer to the semiconductor die, and a second portion closer to the package substrate, and wherein the first portion has a smaller width than the second portion.

In accordance with another aspect of the present invention, a method for forming a package structure includes providing a semiconductor die; providing a package substrate; forming stud bumps on the package substrate; and bonding the semiconductor die to the package substrate, wherein the stud bumps electrically connect the semiconductor die and the package substrate

In accordance with yet another aspect of the present invention, an integrated circuit package structure includes a semiconductor die; a package substrate; and stud bumps between, and electrically connecting, the semiconductor die and the package substrate. The stud bumps each has a first portion closer to the semiconductor die, and a second portion closer to the package substrate, and wherein the first portion has a smaller width than the second portion.

In accordance with yet another aspect of the present invention, an integrated circuit package structure includes a semiconductor die comprising a top surface, and bond pads on the top surface; a package substrate; and stud bumps between, and electrically connecting, each of the bond pads on the semiconductor die to the package substrate. The stud bumps are physically connected to the package substrate, and wherein at least one of the stud bumps is physically spaced apart from respective ones of the bond pads.

By pre-forming stud bumps on package substrates, the damage to semiconductor dies is eliminated.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 2B illustrate conventional methods for forming integrated circuit package structures using stud bumps;

FIGS. 3A through 7 are cross-sectional views of intermediate stages in the manufacturing of an embodiment of the present invention; and

FIGS. 8A and 8B illustrate alternative embodiments of the present invention, wherein dies are bonded to lead frames.

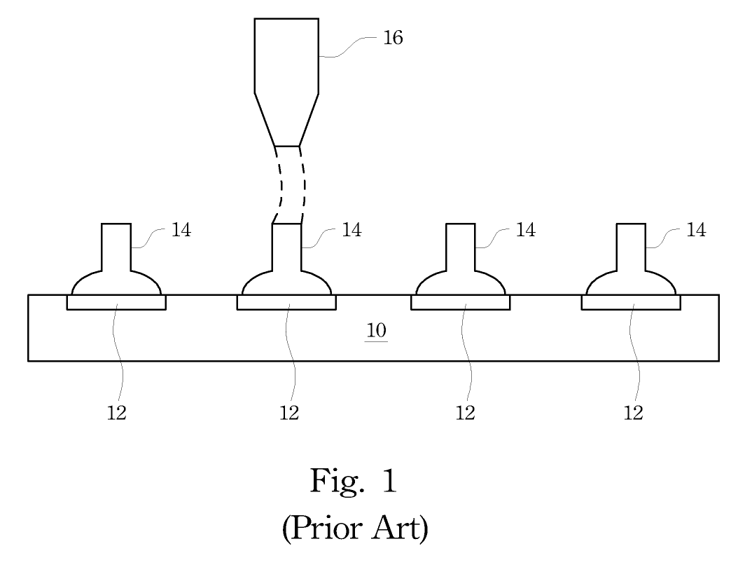

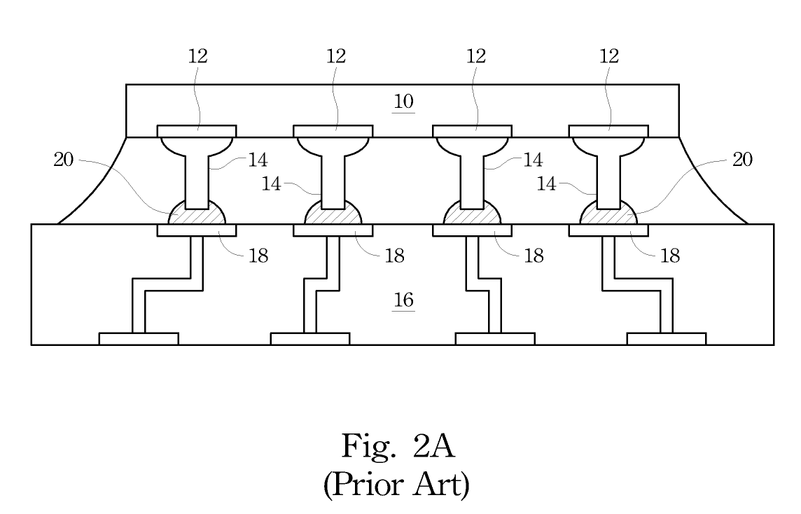

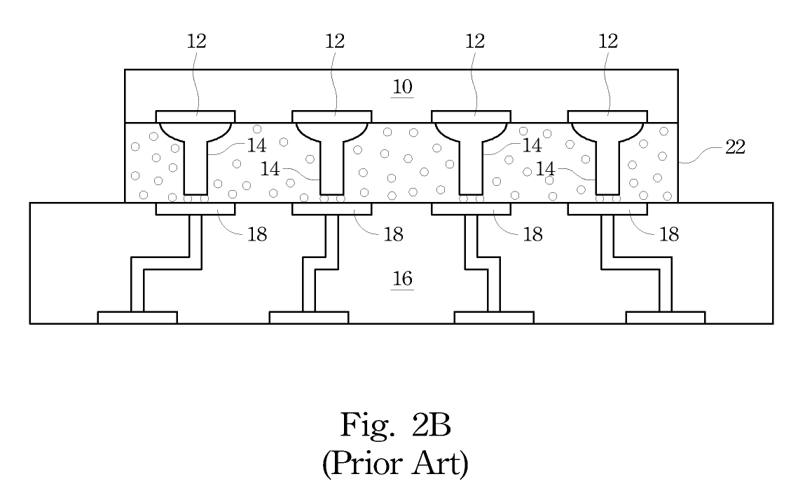

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel packaging structure and the methods for forming the same are provided. The intermediate stages of manufacturing embodiments of the present invention are illustrated. Throughout the various views and illustrative embodiments of the present invention, like reference numbers are used to designate like elements.

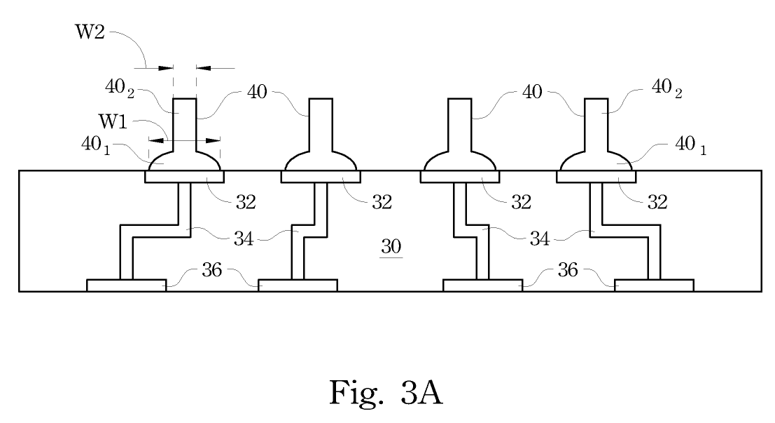

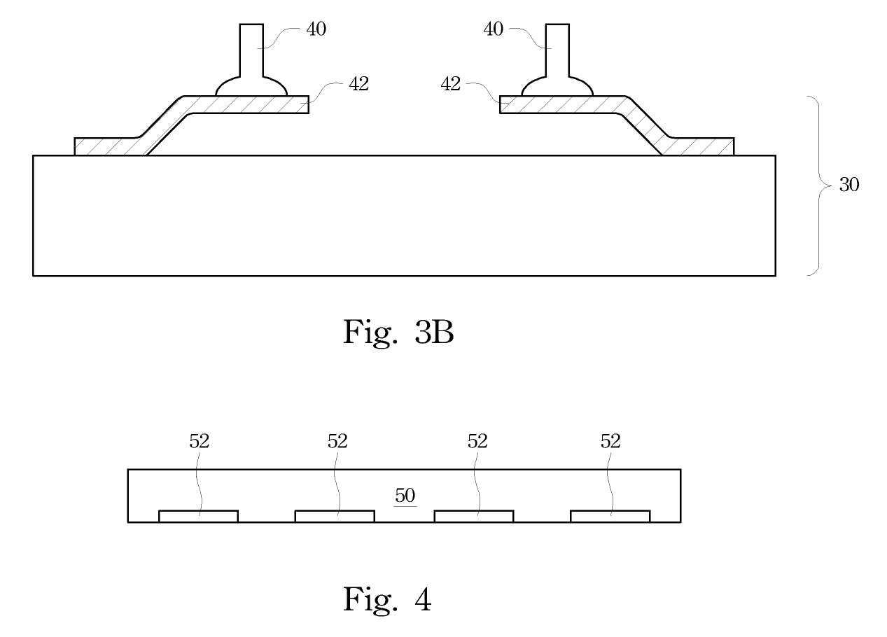

Referring to FIG. 3A, package substrate 30 is provided. In an embodiment, package substrate 30 may be a bismaleimide trianzine (BT) substrate, a print circuit board (PCB) substrate, or other commonly used substrate capable of having dies packaged thereon. Package substrate 30 includes bond pads 32 on a top surface. Bond pads 32 are further connected to redistribution traces 34, which may lead to a bottom surface and connect to bond pads 36. Also, redistribution traces 34 connect to bond pads on the top surface of package substrate 30.

Stud bumps 40 are formed on bond pads 32, for example, using a wire-bonding tool. The stud bumps 40 are formed in a way similar to wire-bonding, except the bond wire is broken, and hence leaving stud bumps 40 on bond pads 32. In the preferred embodiment, stud bumps 40 include gold for its good conductivity and bondability. Stud bumps 40 may also include other metals such as copper. Please note that by such a stud bump formation method, stud bumps 40 each include a base portion 40, and a top portion 402. The width W1 of base portions 40, is substantially greater than width W2 of top portions 402.

In alternative embodiments, as is shown in FIG. 3B, package substrate 30 is a lead frame including a plurality of conductive fingers 42. Stud bumps 40 are formed on fingers 42 using essentially the same method as discussed in preceding paragraphs.

FIG. 4 illustrates semiconductor die 50. As is known in the art, semiconductor dies are formed in the form of semiconductor wafers, each including a plurality of identical dies. After the formation of a semiconductor wafer, the wafer may go through wafer-grinding to reduce its thickness, testing, and die sawing. Die 50 is thus a known-good-die. Die 50 includes bond pads 52 on a top surface, wherein bond pads 52 are connected to the integrated circuit in die 50.

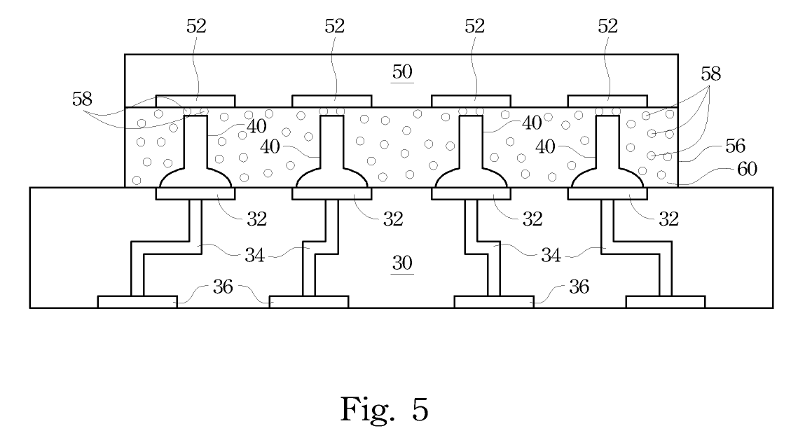

FIG. 5 illustrates the bonding of die 50 onto package substrate 30. Anisotropic conducting film (ACF) 56 is preferably used for the electrical connection between bond pads 52 and stud bumps 40. ACF 56 includes a plurality of conductive particles 58 insulated from each other by non-conductive base material 60, which may be formed of epoxies. In an embodiment of the present invention, ACF 56 is laminated on die 50, a pressure is then applied to compress die 50 and package substrate 30 against each other. Heat is also applied. As a result, bond pads 52 on die 50 and stud bumps 40 are electrically connected through conductive particles 58. Advantageously, by using ACF 56, the neighboring stud bumps 40 and neighboring bond pads 32 are electrically insulated from each other.

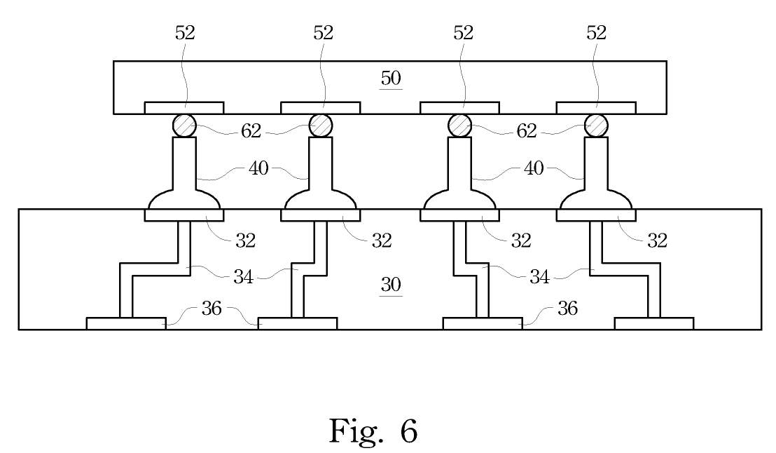

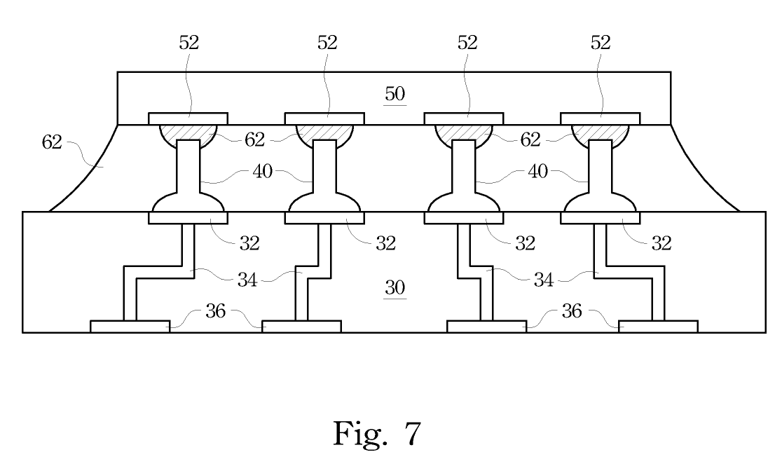

FIGS. 6 and 7 illustrate a further embodiment of the present invention. Referring to FIG. 6, die 50 is placed against package substrate 30, with solder balls 62 between stud bumps 40 and bond pads 52. Solder balls 62 may be pre-placed on bond pads 32 of die 50, along with needed flux (not shown), or pre-placed on stud bumps 40. A reflow is then performed, forming a structure as shown in FIG. 7. The reflowed solder balls 62 electrically connect bond pads 52 and stud bumps 40. Molding compound 62 may thus be applied to protect the package structure.

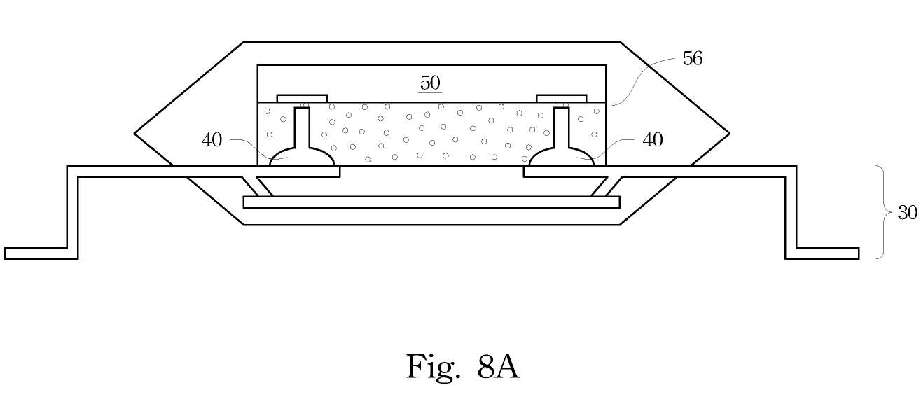

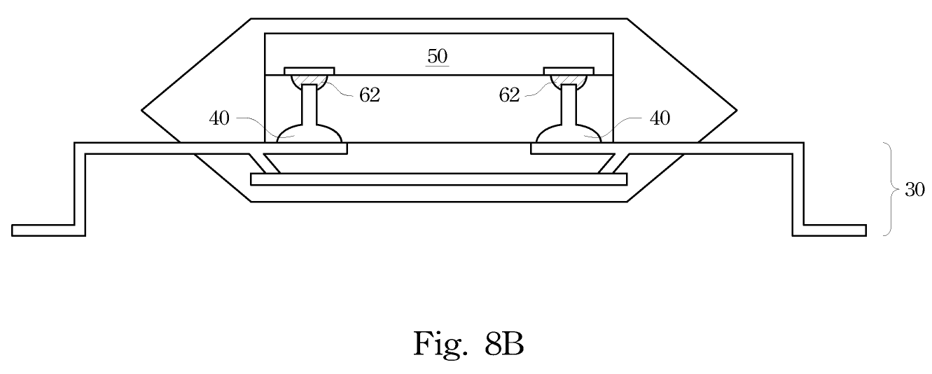

FIGS. 8A and 8B illustrate alternative embodiments, in which dies 50 are bonded to lead frames. In FIG. 8A, and ACF 56 is used to electrically connect die 50 to stud bumps 40. In FIG. 8B, the electrical connection between die 50 and stud bumps 40 is made through solder 62.

In the previously discussed embodiment, package substrate 30 may have a size similar to a semiconductor wafer. In this case, package substrate 30 may include a plurality of sub-regions, each for bonding a die. Either an entire wafer, or a plurality of individual dies separated from each other, may be bonded on package substrate 30.

The embodiments of the present invention have several advantageous features. Since stud bumps 40 are formed on package substrate 30 instead of die 50, the damage to die 50 caused by the force applied during the formation of stud bumps is avoided. Package substrate 30, on the other hand, is less likely to be damaged during the formation of stud bumps since it does not include low-k dielectric materials. Accordingly, even for semiconductor dies having extreme low-k dielectric layers, it is possible to use stud bump technology. Additionally, the throughput for packaging dies is improved. This is because in the conventional packaging techniques, the step of forming stud bumps on dies must be performed before dies are bonded onto substrates. However, in the embodiments of the present invention, stud bumps can be pre-formed on substrates, resulting in the reduction of the cycle time of assembly process.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for forming a package structure, the method comprising:
providing a semiconductor die;
providing a package substrate; and
forming stud bumps between, and electrically connecting, the semiconductor die and the package substrate, wherein the stud bumps each has a first portion closer to the semiconductor die, and a second portion closer to the package substrate, and wherein the first portion has a smaller width than the second portion.

2. The method of claim 1, wherein the step of forming the stud bumps between the semiconductor die and the package substrate comprises:
forming the stud bumps on the package substrate; and
after the step of forming stud bumps on the package substrate, mounting the semiconductor die on the package substrate.

3. The method of claim 2, wherein the semiconductor die and the stud bumps are electrically connected through an anisotropic conducting film.

4. The method of claim 2, wherein the semiconductor die and the stud bumps are electrically connected through solder.

5. The method of claim 1, wherein the semiconductor die is in a semiconductor wafer, and wherein the method further comprises sawing the semiconductor die from the semiconductor wafer after the step of forming the stud bumps between, and electrically connecting, the semiconductor die and the package substrate.

6. The method of claim 1 further comprising sawing the semiconductor die from a semiconductor wafer before the step of forming the stud bumps between, and electrically connecting, the semiconductor die and the package substrate.

7. A method for forming a package structure, the method comprising:
providing a semiconductor die;
providing a package substrate;
forming stud bumps on the package substrate; and
bonding the semiconductor die to the package substrate, wherein the stud bumps electrically connect the semiconductor die and the package substrate.

8. The method of claim 7 further comprising laminating an anisotropic conducting film (ACF) between the semiconductor die and the package substrate, wherein the stud bumps are electrically connected to the semiconductor die through the ACF.

9. The method of claim 7 further, wherein the stud bumps are electrically connected to the semiconductor die through solder.

10. The method of claim 7 wherein the step of bonding comprises:
placing solder balls between the stud bumps and bond pads on a top surface of the semiconductor die; and
reflowing the solder balls to connect the bond pads and the stud bumps.

11. The method of claim 7, wherein the package substrate is selected from the group consisting essentially of a glass substrate, a bismaleimide trianzine substrate, and a print circuit board.

12. The method of claim 7, wherein the package substrate is a lead frame, and wherein the stud bumps are formed on fingers of the lead frame.

13. The method of claim 7 further comprising:
providing a semiconductor wafer; and
sawing the semiconductor die from the semiconductor wafer before the step of bonding.

14. The method of claim 7, wherein the semiconductor die is in a semiconductor wafer, and wherein the method further comprises sawing the semiconductor wafer after the step of bonding the semiconductor die to the package substrate.

15. An integrated circuit package structure comprising:
a semiconductor die;
a package substrate; and
stud bumps between, and electrically connecting, the semiconductor die and the package substrate, wherein the stud bumps each has a first portion closer to the semiconductor die, and a second portion closer to the package substrate, and wherein the first portion has a smaller width than the second portion.

16. The integrated circuit package structure of claim 15, wherein the semiconductor die comprises bond pads on a top surface of the semiconductor die, and wherein the integrated circuit package structure further comprises solder between the stud bumps and the bond pads.

17. The integrated circuit package structure of claim 15 further comprising an anisotropic conducting film (ACF) between the semiconductor die and the package substrate, wherein the semiconductor die comprises bond pads on a top surface, and wherein the stud bumps are electrically connected to the bond pads through conductive particles in the ACF.

18. The integrated circuit package structure of claim 15, wherein the package substrate is selected from the group consisting essentially of a glass substrate, a bismaleimide trianzine substrate, and a print circuit board.

19. The integrated circuit package structure of claim 15, wherein the package substrate is a lead frame, and wherein the stud bumps are formed on fingers of the lead frame.

20. An integrated circuit package structure comprising:
a semiconductor die comprising a top surface, and bond pads on the top surface;
a package substrate; and
stud bumps between, and electrically connecting, each of the bond pads on the semiconductor die to the package substrate, wherein the stud bumps are physically connected to the package substrate, and wherein at least one of the stud bumps is physically spaced apart from respective ones of the bond pads.

21. The integrated circuit package structure of claim 20 further comprising a solder material between the bond pads and the stud bumps.

22. The integrated circuit package structure of claim 20 further comprising an anisotropic conducting film (ACF), wherein conductive particles in the ACF connect the bond pads and the stud bumps.
